(19) United States
(12) Patent Application Publication
(10) Pub. No.: US 2020/0303303 A1
(43) Pub. Date: Sep. 24, 2020

(54) SEMICONDUCTOR DEVICES AND DISPLAY DRIVER INTEGRATED CIRCUITS INCLUDING THE SEMICONDUCTOR DEVICES

(71) Applicant: Samsung Electronics Co., Ltd., Suwon-si (KR)

(72) Inventor: MYOUNG SOO KIM, Hwaseong-si (KR)

(21) Appl. No.: 16/590,545

(22) Filed: Oct. 2, 2019

(30) Foreign Application Priority Data
Mar. 22, 2019 (KR) 10-2019-0032792

(51) Int. Cl. H01L 23/522; H01L 23/482

(52) U.S. Cl. CPC H01L 23/5228; G09G 3/20; H01L 23/4824

(57) ABSTRACT

A semiconductor device is provided that is capable of enhancing a layout efficiency by providing a plurality of gamma voltages using a resistive line of a single body. The semiconductor device may include a plurality of connection structures arranged in a first direction, a resistive line connected to the plurality of connection structures and including a plurality of resistive regions arranged in the first direction, each of the resistive regions being defined between a respective pair of adjacent connection structures of the plurality of connection structures, and a plurality of conductive pads on the plurality of connection structures and connected to the resistive line. At least two of the plurality of conductive pads are configured for use as voltage nodes.

### CROSS-REFERENCE TO RELATED APPLICATION

This application claims priority and all benefits under 35 U.S.C. § 119 accruing therefrom to Korean Patent Application No. 10-2019-0032792, filed on Mar. 22, 2019, the disclosure of which is incorporated by reference herein in its entirety.

### BACKGROUND

### 1. Technical Field

The present disclosure relates to semiconductor devices and to display driver integrated circuits including the same.

### 2. Description of the Related Art

A display device may include a display panel for displaying an image, a data driving unit for supplying data to data lines, a gate driving unit for supplying a scan pulse to the gate lines, and a timing controller for controlling the data driving unit and the gate driving unit.

The data driving unit receives a distributed voltage branching from a resistor structure and outputs the distributed voltage through a decoder. If the distributed voltage provided to the data driving unit is not provided stably, an image to be displayed may be distorted or may not be displayed on a display panel. Research is being conducted on a resistor structure for providing a stable distributed voltage to the data driving unit.

### SUMMARY

Some aspects of the present disclosure provide semiconductor devices with enhanced layout efficiency by providing a plurality of gamma voltages using a resistive line of a single body.

Some aspects of the present disclosure provide semiconductor devices with improved reliability by providing a gamma voltage with reduced deviation using a resistive line of a single body.

Some aspects of the present disclosure provide a display driver integrated circuits including semiconductor device with increased layout efficiency and improved reliability.

However, aspects of the present disclosure are not restricted to those set forth herein. The above and other aspects of the present disclosure will become more apparent to one of ordinary skill in the art to which the present inventive concepts pertain through reference to the detailed description of the present inventive concepts provided herein.

According to some aspects of the present inventive concepts, there is provided a semiconductor device comprising a plurality of connection structures arranged in a first direction, a resistive line connected to the plurality of connection structures and including a plurality of resistive regions arranged in the first direction, each of the resistive regions being defined between a respective pair of adjacent connection structures of the plurality of connection structures, and a plurality of conductive pads on the plurality of connection structures and connected to the resistive line. Some of the plurality of conductive pads are configured for use as voltage nodes.

According to some aspects of the present inventive concepts, there is provided a semiconductor device comprising a resistive line extending in one direction, a plurality of connection structures connected to the resistive line and spaced at equal intervals in the one direction, and a plurality of conductive pads on a first metal level and connected to at least some of the plurality of connection structures. The plurality of connection structures includes a plurality of lower contacts spaced on the resistive line in the one direction, and a plurality of conductive insertion pads, each conductive insertion pad corresponding to a respective one of the plurality of lower contacts and connected thereto, and each conductive insertion pad at a second metal level lower than the first metal level.

According to some aspects of the present inventive concepts, there is provided a semiconductor device comprising a resistive line extending in one direction, first, second, and third lower contacts connected to the resistive line and arranged in the one direction, first, second, and third conductive insertion pads at a first metal level and corresponding respectively to the first to third lower contacts and connected thereto, a first conductive pad at a second metal level higher than the first metal level, connected to the first conductive insertion pad, and configured to provide a first distributed voltage, and a second conductive pad at the second metal level, connected to the third conductive insertion pad, and configured to provide a second distributed voltage different from the first distributed voltage. The second conductive insertion pad is at the second metal level and is not connected to a conductive pad configured to provide a voltage.

According to some aspects of the present inventive concepts, there is provided a semiconductor device comprising a resistive line extending in a first direction, a first end of the resistive line configured to connect to a first voltage, and a second end of the resistive line that is opposite from the first end of the resistive line in the first direction and that is configured to connect to a second voltage different from the first voltage, and a plurality of conductive pads each connected to the resistive line and configured for use as a voltage node. Each of the plurality of conductive pads is configured to provide a different voltage between the first voltage and the second voltage.

According to some aspects of the present inventive concepts, there is provided a semiconductor device comprising first and second resistive lines, a plurality of first voltage node structures connected to the first resistive line, each first voltage node structure including a first connection structure and a first conductive pad on the first connection structure, a plurality of second voltage node structures connected to the second resistive line, each second voltage node structure including a second connection structure and a second conductive pad on the second connection structure, and a connection conductive pad connecting the first resistive line and the second resistive line. Each first voltage node structure is configured to provide a different voltage, and each second voltage node structure is configured to provide a different voltage.

According to some aspects of the present inventive concepts, there is provided a display driver integrated circuit comprising a gamma circuit configured to provide a plurality of gamma voltages, and a source driver including a plurality of decoders configured to select and output one of the plurality of gamma voltages provided from the gamma circuit. The gamma circuit includes a plurality of connection structures arranged in a first direction, a resistive line including a plurality of resistive regions connected to the plurality of connection structures and arranged in the first direction, each of the resistive regions being defined between a respective pair of adjacent connection structures of the plurality of connection structures, and a plurality of conductive pads on the plurality of connection structures and connected to the resistive line. Each of the plurality of conductive pads is configured to provide a respective one of the plurality of gamma voltages.

### BRIEF DESCRIPTION OF THE DRAWINGS

The above and other aspects and features of the present inventive concepts will become more apparent in the description herein of example embodiments thereof and with reference to the attached drawings, in which:

FIG. 1 is a circuit diagram of a resistor structure included in a semiconductor device according to some embodiments;

FIG. 2 is a layout diagram illustrating a semiconductor device according to some embodiments;

FIGS. 3 and 4 are cross-sectional views taken along the lines A-A and B-B of FIG. 2;

FIG. 5 is a diagram illustrating a semiconductor device according to some embodiments;

FIG. 6 is a diagram illustrating a semiconductor device according to some embodiments;

FIG. 7 is a diagram illustrating a semiconductor device according to some embodiments;

FIG. 8 is a diagram illustrating a semiconductor device according to some embodiments;

FIGS. 9 and 10 are diagrams illustrating a semiconductor device according to some embodiments;

FIG. 11 is a diagram illustrating a semiconductor device according to some embodiments;

FIG. 12 is a diagram illustrating a semiconductor device according to some embodiments;

FIG. 13 is a diagram illustrating a semiconductor device according to some embodiments;

FIGS. 14 and 15 are diagrams illustrating a semiconductor device according to some embodiments;

FIG. 16 is a layout diagram illustrating a semiconductor device according to some embodiments;

FIG. 17 is a cross-sectional view taken along line C-C of FIG. 16;

FIG. 18 is a layout diagram illustrating a semiconductor device according to some embodiments;

FIG. 19 is a cross-sectional view taken along line B-B of FIG. 18;

FIG. 20 is a layout diagram illustrating a semiconductor device according to some embodiments;

FIG. 21 is a cross-sectional view taken along line B-B of FIG. 20;

FIG. 22 is a diagram illustrating resistive lines included in a semiconductor device according to some embodiments;

FIG. 23 is a diagram illustrating a plurality of resistive lines included in a semiconductor device according to some embodiments;

FIG. 24 is a diagram illustrating a plurality of resistive lines included in a semiconductor device according to some embodiments; and

FIG. 25 is a diagram schematically illustrating a display driver integrated circuit including a semiconductor device according to some embodiments.

### DETAILED DESCRIPTION OF THE EMBODIMENTS

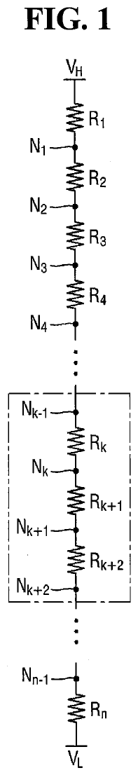

FIG. 1 is a circuit diagram of a resistor structure included in a semiconductor device according to some embodiments.

In the resistor structure of FIG. 1, n resistors R₁ to Rₙ may be connected in series between a first voltage V_{H} and a second voltage V_{L} smaller than the first voltage V_{H}. The resistor structure of FIG. 1 may also include n−1 voltage nodes N₁ to Nₙ₋₁, each of which may be between a pair of the n resistors R₁ to Rₙ connected in series.

In some embodiments, a portion in which the first voltage V_{H} and the second voltage V_{L} are connected may also be considered as voltage nodes, and as such, n+1 voltage nodes may exist between the first voltage V_{H} and the second voltage V_{L}.

At the voltage nodes N₁ to Nₙ₋₁ between the resistors R₁ to Rₙ, a respective distributed voltage may be extracted. Each distributed voltage is smaller than the first voltage V_{H} and larger than the second voltage V_{L}.

The extracted distributed voltages may be provided to integrated circuits and the like which are connected to the respective voltage nodes N₁ to Nₙ₋₁. Each voltage node N₁ to Nₙ₋₁ may be a node for extracting a distributed voltage between the first voltage V_{H} and the second voltage V_{L}.

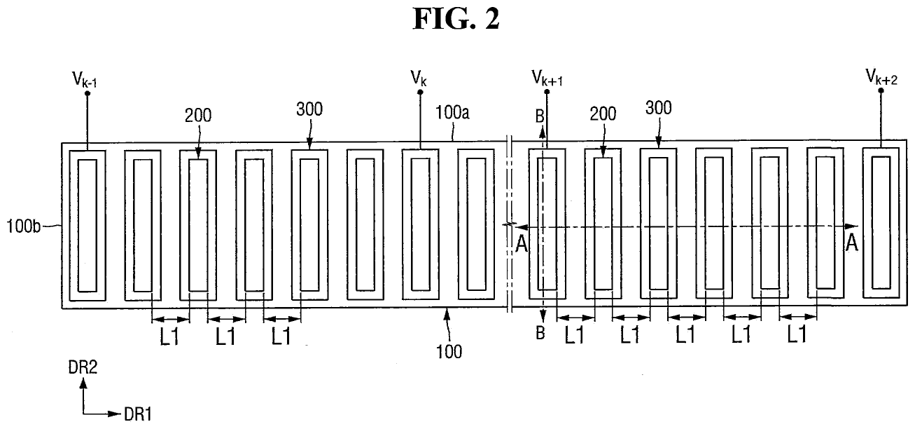

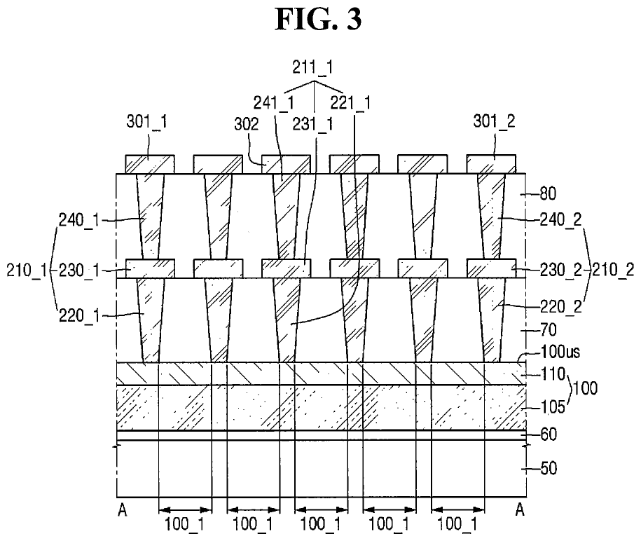

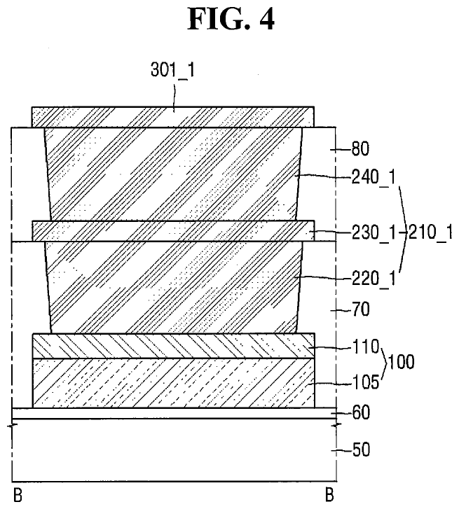

FIG. 2 is a layout diagram illustrating a semiconductor device according to some embodiments. FIGS. 3 and 4 are cross-sectional views taken along the lines A-A and B-B of FIG. 2. For reference, FIG. 2 may be an exemplary layout diagram for implementing a part (a dotted line part) of FIG. 1.

Referring to FIGS. 2 to 4, the semiconductor device according to some embodiments may include a first resistive line 100, a plurality of first connection structures 200, and a plurality of conductive pads 300.

The first resistive line 100 may be disposed on a substrate 50. The first resistive line 100 may be disposed on a first insulating film 60 formed along an upper surface of the substrate 50.

The substrate 50 may be bulk silicon or silicon-on-insulator (SOI). In some embodiments, the substrate 50 may be a silicon substrate or may include other materials, but is not limited thereto. For example, the substrate 50 may be or may include silicon germanium, silicon germanium on insulator (SGOI), indium antimonide, lead tellurium compound, indium arsenide, phosphide indium, gallium arsenide or gallium antimonide. In the following description, the substrate 50 will be described as a silicon substrate.

The first insulating film 60 may include, for example, at least one of silicon oxide (SiO), silicon nitride (SiN), silicon oxynitride (SiON), silicon carbonitride (SiCN), and silicon oxycarbonitride (SiOCN).

The first resistive line 100 may extend long in a first direction DR1. The first resistive line 100 may include first and second long sidewalls 100a extending substantially in the first direction DR1, and first and second short sidewalls 100b extending substantially in a second direction DR2. The second direction DR2 may be perpendicular or substantially perpendicular to the first substrate DR1. The short sidewalls 100b of the first resistive line connect the long sidewalls 100a of the first resistive line facing each other. A length of a long sidewall 100a of the first resistive line in the first direction DR1 is greater than a length of a short sidewall 100b of the first resistive line in the second direction DR2.

The first resistive line 100 may include a semiconductor pattern 105 and a silicide film 110. The semiconductor pattern 105 may be disposed on the first insulating film 60. The silicide film 110 may be disposed on the semiconductor pattern 105.

For example, the silicide film 110 may be formed entirely along the upper surface of the semiconductor pattern 105. An upper surface 100us of the first resistive line 100 may be defined by the silicide film 110, but is not limited thereto.

The semiconductor pattern 105 may include, for example, at least one of silicon (Si) and silicon germanium (SiGe). As an example, the semiconductor pattern 105 may include doped n-type impurities. As another example, the semiconductor pattern 105 may include doped p-type impurities. Alternatively, the semiconductor pattern 105 may include at least one of undoped silicon and undoped silicon germanium.

The silicide film 110 may include a material in which metal is silicided. For example, the silicide film 110 may include, but is not limited to, at least one of nickel silicide (NiSi), titanium silicide (TiSi), platinum silicide (PtSi), palladium silicide (PdSi), cobalt silicide (CoSi), tungsten silicide (WSi), chromium silicide (CrSi), molybdenum silicide (MoSi), tantalum silicide (TaSi) or erbium silicide (ErSi).

The first resistive line 100 may be a single body. When there is a voltage difference between one end of the first resistive line 100 defined on the short sidewall 100b of the first resistive line and the other end of the first resistive line 100, the entire first resistive line 100 may be used as a continuous current path from one end of the first resistive line 100 to the other end of the first resistive line 100. Described differently, the first resistive line 100 may be formed as a unitary component, rather than by connecting a plurality of resistive lines separated by an insulating pattern or patterns.

The first resistive line 100 may include a plurality of resistive regions 100_1. The plurality of resistive regions 100_1 may be arranged along the first direction DR1. The plurality of resistive regions 100_1 may be connected in series with one another. Each resistive region 100_1 may be a unit resistive region used in calculating the distributed voltage to be extracted. The description of the resistive region 100_1 will be described in greater detail herein.

A first end of the first resistive line 100 may be connected to a first voltage (e.g., V_{H} of FIG. 1), and a second end of the first resistive line 100 opposite from the first end may be connected to a second voltage lower than the first voltage (e.g., V_{L} of FIG. 1). A plurality of resistors Rₖ, Rₖ₊₁, and Rₖ₊₂ may be included from the first resistive line 100. The first resistive line 100 may be connected to a plurality of voltage nodes Nₖ₋₁, Nₖ, Nₖ₊₁, and Nₖ₊₂. That is, a plurality of distributed voltages Vₖ₋₁, Vₖ, Vₖ₊₁, and Vₖ₊₂ may be extracted using the first resistive line 100. For example, the first resistive line 100 may be connected to at least three or more voltage nodes.

Although FIG. 2 illustrates four distributed voltages that are extracted using the first resistive line 100, this is only for the convenience of description, and the inventive concepts provided herein are not limited thereto.

The second insulating film 70 and the third insulating film 80 may be sequentially formed on the first insulating film 60. The third insulating film 80 may be disposed on the second insulating film 70.

The second insulating film 70 may be disposed on the long sidewall 100a of the first resistive line and the short sidewall 100b of the first resistive line 100, as best seen in FIG. 4. In other words, the second insulating film 70 may contact substantially vertical surfaces of the long sidewalls 100a and short sidewalls 100b of the first resistive line 100. The second insulating film 70 may cover the first resistive line 100, and/or may cover the upper surface 100us of the first resistive line 100.

The second insulating film 70 and the third insulating film 80 may each include, for example, at least one of silicon oxide, silicon nitride, silicon oxynitride, and low dielectric constant material. In FIGS. 3 and 4, the second insulating film 70 and the third insulating film 80 are each illustrated as a single film, but this is only for the convenience of explanation, and the inventive concepts provided herein are not limited thereto.

The low dielectric constant material may be, for example, a silicon oxide with suitably high carbon and hydrogen, and may be a material such as SiCOH. The inclusion of carbon in the insulating material may lower the dielectric constant of the insulating material. However, in order to further lower the dielectric constant of the insulating material, the insulating material may include a pore, such as a cavity in which gas or air is filled or inserted in the insulating material.

The low dielectric materials may include, but are not limited to, for example, Fluorinated TetraethylEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The plurality of connection structures 200 may be disposed on the first resistive line 100. The plurality of connection structures 200 may be connected to the first resistive line 100.

The plurality of connection structures 200 may be arranged along the first direction DR1. In the semiconductor device according to some embodiments, the plurality of connection structures 200 may be arranged at equal intervals along the first direction DR1. For example, a distance between adjacent connection structures 200 may be a first distance L1. Adjacent connection structures 200 may be spaced apart from each other.

Resistive regions 100_1 of the first resistive line 100 may be defined between the connection structures 200, with each resistive region 100_1 defined between a pair of adjacent connection structures 200. When the connection structures of the plurality of connection structures 200 are arranged at equal intervals along the first direction DR1, each resistive region 100_1 may have the same width in the first direction DR1.

The plurality of connection structures 200 may include at least one first node connection structure 210_1, at least one second node connection structure 210_2, and at least one first dummy node connection structure 211_1. FIG. 3 shows a plurality of first dummy node connection structures 211_1 arranged in the first direction DR1 between a first node connection structure 210_1 and a second node connection structure 210_2. However, this is only for the convenience of the description and the inventive concepts provided herein are not limited thereto. Additionally, for convenience of the description, only a first of the dummy node connection structures 211_1 is described in detail.

The first node connection structure 210_1, the second node connection structure 210_2, and the first dummy node connection structure 211_1 may be spaced apart from each other.

Each of the plurality of connection structures 200 may be formed in the second insulating film 70 and the third insulating film 80. Each of the plurality of connection structures 200 may include a portion formed in the second insulating film 70 and a portion formed in the third insulating film 80.

The first node connection structure 210_1, the second node connection structure 210_2, and the first dummy node connection structure 211_1 may include lower contacts 220_1, 220_2, and 221_1, conductive insertion pads 230_1, 230_2, and 231_1, and upper contacts 240_1, 240_2, and 241_1, respectively.

The first node connection structure 210_1, the second node connection structure 210_2, and the first dummy node connection structure 211_1 may have the same stacked structure. In the semiconductor device according to some embodiments, the first node connection structure 210_1, the second node connection structure 210_2, and the first dummy node connection structure 211_1 may include a single lower contact 220_1, 220_2, and 221_1, a conductive insertion pad 230_1, 230_2, and 231_1, and an upper contact 240_1, 240_2, and 241_1, respectively.

The plurality of lower contacts 220_1, 220_2, and 221_1 may be formed in the second insulating film 70. The plurality of lower contacts 220_1, 220_2, and 221_1 may be disposed on the first resistive line 100, such as, for example, on the upper surface 100us of the first resistive line 100. The plurality of lower contacts 220_1, 220_2, and 221_1 may be connected to the first resistive line 100. For example, the plurality of lower contacts 220_1, 220_2, and 221_1 may be in contact with the first resistive line 100.

The plurality of lower contacts 220_1, 220_2, and 221_1 may be arranged along the first direction DR1. In the semiconductor device according to some embodiments, the plurality of lower contacts 220_1, 220_2, and 221_1 may be arranged at equal intervals along the first direction DR1. The lower contacts 220_1, 220_2, and 221_1 are spaced apart from one another.

A plurality of conductive insertion pads 230_1, 230_2, and 231_1 may be disposed on the plurality of lower contacts 220_1, 220_2, and 221_1. For example, the plurality of lower contacts 220_1, 220_2, and 221_1 may be disposed at a first metal level.

Each conductive insertion pad 230_1, 230_2, and 231_1 may be connected to a corresponding lower contact 220_1, 220_2, and 221_1. For example, each conductive insertion pad 230_1, 230_2, and 231_1 may be in contact with the corresponding lower contact 220_1, 220_2, and 221_1.

The plurality of conductive insertion pads 230_1, 230_2, and 231_1 may be arranged along the first direction DR1. The conductive insertion pads 230_1, 230_2, and 231_1 are spaced apart from one another.

A plurality of upper contacts 240_1, 240_2, and 241_1 may be disposed on the plurality of conductive insertion pads 230_1, 230_2, and 231_1. Each upper contact 240_1, 240_2, and 241_1 may be connected to a corresponding conductive insertion pad 230_1, 230_2, and 231_1. For example, each upper contact 240_1, 240_2, and 241_1 may be in contact with the corresponding conductive insertion pad 230_1, 230_2, and 231_1.

The plurality of upper contacts 240_1, 240_2, and 241_1 may be arranged along the first direction DR1. The upper contacts 240_1, 240_2, and 241_1 are spaced apart from one another.

The conductive insertion pads 230_1, 230_2, and 231_1 and the upper contacts 240_1, 240_2, and 241_1 may be formed in the third insulating film 80.

In the semiconductor device according to some embodiments, the connection structure 200 may include the same number of lower contacts, conductive insertion patterns, and upper contacts. That is, a number of lower contacts may equal a number of conductive insertion patterns and equal a number of upper contacts.

Each of the lower contacts 220_1, 220_2, and 221_1, the conductive insertion pads 230_1, 230_2, and 231_1 and the upper contacts 240_1, 240_2, and 241_1 may include, for example, at least one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), copper (Cu), aluminum (Al), zirconium (Zr), zirconium nitride (ZrN), vanadium (V), vanadium nitride (VN), niobium (Nb), niobium nitride (NbN), platinum (Pt), iridium (Ir) and rhodium (Rh).

In FIGS. 3 and 4, each of the lower contacts 220_1, 220_2, and 221_1 and the upper contacts 240_1, 240_2, and 241_1 is illustrated as having a line type shape extending substantially in the second direction DR2, but the inventive concepts are not limited thereto.

In FIG. 3 and FIG. 4, although each of the lower contacts 220_1, 220_2, and 221_1 and the upper contacts 240_1, 240_2, and 241_1 is illustrated as being formed as a single contact, in some embodiments each lower contact and/or each upper contact may have a structure in which a plurality of contacts are stacked.

The plurality of conductive pads 300 may be disposed on the plurality of connection structures 200. The plurality of conductive pads 300 may be connected to the first resistive line 100. The plurality of conductive pads 300 may be connected to the first resistive line 100 via the connection structure 200.

The plurality of conductive pads 300 may be connected to at least some of the plurality of connection structures 200. In the semiconductor device according to some embodiments, each of the plurality of connection structures 200 may be connected to one of the plurality of conductive pads 300.

As an example, one conductive pad 300 may be connected to one connection structure 200. The number of the plurality of connection structures 200 may be equal to the number of the plurality of conductive pads 300.

As another example, one conductive pad 300 may be connected to multiple of the plurality of connection structures 200. The number of the plurality of connection structures 200 is greater than the number of the plurality of conductive pads 300.

The plurality of conductive pads 300 may include at least one first conductive node pad 301_1, at least one second conductive node pad 301_2, and at least one conductive dummy pad 302. FIG. 3 shows a plurality of conductive dummy pads 302 arranged in the first direction DR1 between a first conductive node pad 301_1 and a second conductive node pad 301_2. However, this is only for the convenience of the description and the inventive concepts provided herein are not limited thereto. Additionally, for convenience of the description, only a first of the conductive dummy pads 302 is described in detail. The first conductive node pad 301_1 and the second conductive node pad 301_2 may be included in a node pad group, where each conductive pad 300 in the node pad group may be used as a voltage node. The conductive dummy pad 302 may be included in a non-node pad group, where each conductive pad 300 in the non-node pad group is not used as a voltage node.

In other words, the first conductive node pad 301_1 and the second conductive node pad 301_2 may be voltage nodes for extracting a distributed voltage. The conductive dummy pad 302 is not a voltage node for extracting a distributed voltage.

In FIG. 2, the plurality of conductive pads 300 may be arranged along the first direction DR1. Some parts of the plurality of conductive pads 300 are used as a voltage node, and the remaining parts of the plurality of conductive pads 300 are not used as a voltage node. The plurality of conductive pads 300 connected to the first resistive line 100 formed as a single body includes both a node pad group and a non-node pad group.

One or more conductive pads 300 included in the non-node pad group are illustrated as being disposed between two conductive pads 300 included in the node pad group that are adjacent to each other, but the inventive concepts are not limited thereto. In some embodiments, a conductive pad 300 included in the non-node pad group may not be disposed between two adjacent conductive pads 300 included in the node pad group.

The first conductive node pad 301_1, the second conductive node pad 301_2 and the conductive dummy pad 302 may be disposed at a second metal level higher than the first metal level. The first conductive node pad 301_1, the second conductive node pad 301_2, and the conductive dummy pad 302 may be disposed on the first node connection structure 210_1, the second node connection structure 210_2, and the first dummy node connection structure 211_1, respectively.

The first conductive node pad 301_1 may be connected to the corresponding first node connection structure 210_1. The first conductive node pad 301_1 may be in contact with the first node connection structure 210_1.

The second conductive node pad 301_2 may be connected to the corresponding second node connection structure 210_2. The second conductive node pad 301_2 may be in contact with the second node connection structure 210_2.

The conductive dummy pad 302 may be connected to the corresponding first dummy node connection structure 211_1. The conductive dummy pad 302 may be in contact with the first dummy node connection structure 211_1.

The first node connection structure 210_1 and the second node connection structure 210_2 are connected to a conductive pad 300 used as a voltage node (e.g., the first conductive node pad 301_1 or the second conductive node pad 301_2, respectively). The first dummy node connection structure 211_1 is connected to a conductive pad 300 which is not used as a voltage node (e.g., the conductive dummy pad 302).

The plurality of upper contacts 240_1, 240_2, and 241_1 may correspond to the plurality of conductive pads 300. The plurality of upper contacts 240_1, 240_2, and 241_1 may correspond respectively to the first conductive node pad 301_1, the second conductive node pad 301_2 and the conductive dummy pad 302. Each upper contact 240_1, 240_2, and 241_1 may connect one of the conductive insertion pads 230_1, 230_2, and 231_1 to one of the plurality of conductive pads 300. That is, one conductive pad 300 may be connected to one connection structure 200.

As used herein, the expression “a connection structure is connected to a conductive pad” means that the connection structure is connected to the conductive pad without passing through the first resistive line 100.

Each of the first conductive node pad 301_1, the second conductive node pad 301_2, and the conductive dummy pad 302 may include, for example, at least one of tantalum (Ta), tantalum nitride (TaN), titanium (TaN), titanium nitride (TiN), ruthenium (Ru), cobalt (Co), nickel (Ni), nickel boron (NiB), tungsten (W), tungsten nitride (WN), tungsten carbonitride (WCN), copper (Cu), aluminum (Al), zirconium (Zr), zirconium nitride (ZrN), vanadium (V), vanadium nitride (VN), niobium (Nb), niobium nitride (NbN), platinum (Pt), iridium (Ir), and rhodium (Rh).

The first conductive node pad 301_1 may be used as a voltage node from which the first distributed voltage Vₖ₊₁ is extracted. The second conductive node pad 301_2 may be used as a voltage node from which the second distributed voltage Vₖ₊₂ is extracted. The connected conductive node pads 301_1 and 301_2 and the node connection structures 210_1 and 210_2 may be a voltage node structure used for extracting distributed voltages.

A conductive pad used as a voltage node may not be between the first conductive node pad 301_1 and the second conductive node pad 301_2, which are used as voltage nodes. However, a conductive dummy pad 302 not used as a voltage node may be between the first conductive node pads 301_1 and the second conductive node pads 301_2 used as the voltage nodes.

That is, between the first node connection structure 210_1 and the second node connection structure 210_2 connected respectively to the first conductive node pad 301_1 and the second conductive node pad 301_2, one or more first dummy node connection structures 211_1 connected to one or more conductive dummy pads 302 may be disposed.

In FIGS. 3 and 4, each of the lower contacts 220_1, 220_2, and 221_1, the conductive insertion pads 230_1, 230_2, and 231_1, the upper contacts 240_1, 240_2, and 241_1, the first conductive node pads 301_1, the second conductive node pad 301_2 and the conductive dummy pad 302 are illustrated as a single film or structure. However, this is only for convenience of description and the inventive concepts provided herein are not limited thereto.

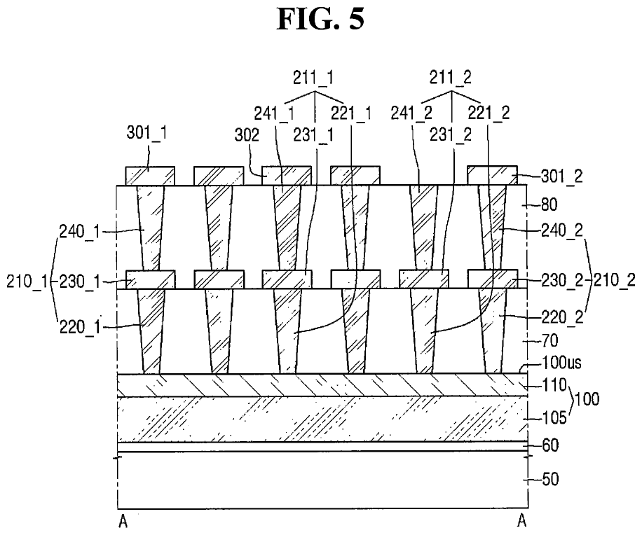

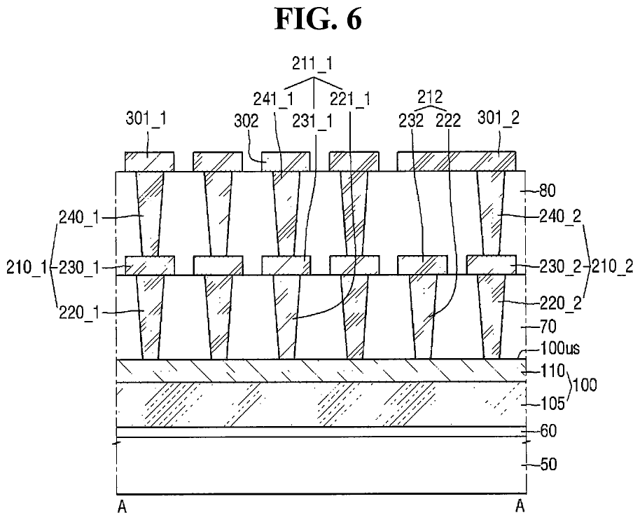

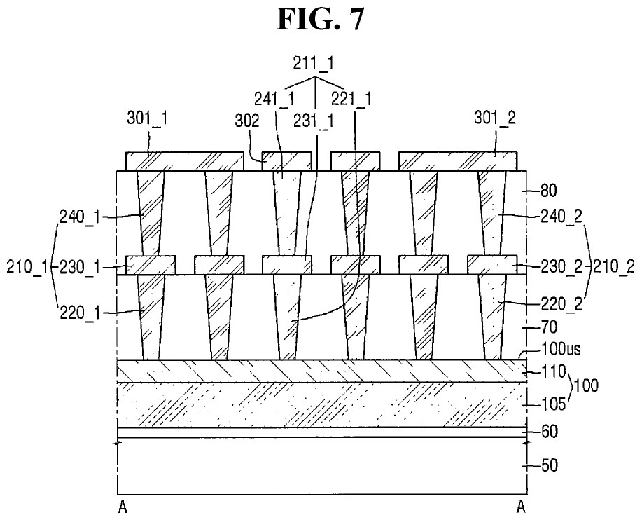

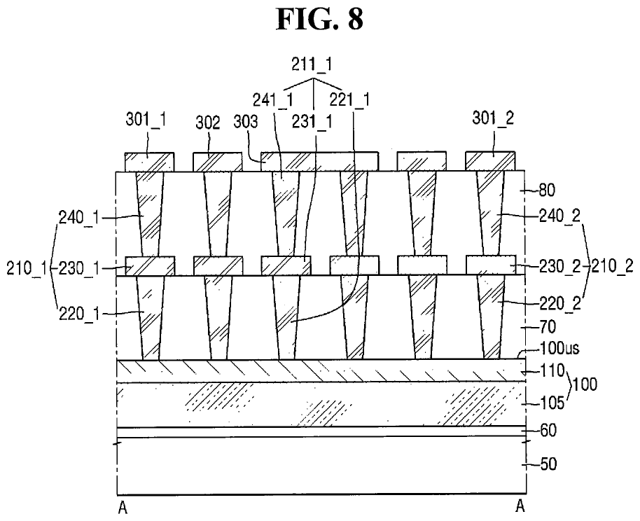

FIG. 5 is a diagram illustrating a semiconductor device according to some embodiments. FIG. 6 is a diagram illustrating a semiconductor device according to some embodiments. FIG. 7 is a diagram illustrating a semiconductor device according to some embodiments. FIG. 8 is a diagram illustrating a semiconductor device according to some embodiments. For convenience of explanation, aspects presented within FIGS. 5-8 differing from those described using FIGS. 2 to 4 will be mainly described, and repetitive description may be omitted in the interest of brevity. For reference, FIGS. 5 through 8 are each cross-sectional views taken along line A-A of FIG. 2.

Referring to FIG. 5, in a semiconductor device according to some embodiments, the plurality of connection structures 200 may include at least one first node connection structure 210_1, at least one second node connection structure 210_2, at least one first dummy node connection structure 211_1, and at least one second dummy node connection structure 211_2.

The second dummy node connection structure 211_2 may include a lower contact 221_2, a conductive insertion pad 231_2, and an upper contact 241_2. The description of the structure of the second dummy node connection structure 211_2 may be substantially the same as the description of the structure of the first dummy node connection structure 211_1.

A conductive dummy pad 302 may not be formed on the second dummy node connection structure 211_2. That is, the second dummy node connection structure 211_2 is not connected to a conductive dummy pad 302.

At least one first dummy node connection structure 211_1 connected to a corresponding conductive dummy pad 302, and at least one second dummy node connection structure 211_2 not connected to a corresponding conductive dummy pad 302 may be disposed between the first node connection structure 210_1 and the second node connection structure 210_2.

Each present conductive pad 300 is connected to a respective connection structure 200, and the number of the plurality of connection structures 200 is larger than the number of the plurality of conductive pads 300.

Referring to FIG. 6, in a semiconductor device according to some embodiments, the plurality of connection structures 200 may include at least one first node connection structure 210_1, at least one second node connection structure 210_2, at least one first dummy node connection structure 211_1, and at least one third dummy node connection structure 212.

The third dummy node connection structure 212 may include a lower contact 212 corresponding to the lower contact 221_1 of the first dummy node connection structure 211_1, and a conductive insertion pad 232 corresponding to the conductive insertion pad 231_1 of the first dummy node connection structure of 211_1. However, the third dummy node connection structure 212 may lack an upper contact corresponding to the upper contact 241_1 of the first dummy node connection structure 211_1.

Since the third dummy node connection structure 212 does not include the upper contact formed between the first metal level and the second metal level, the third dummy node connection structure 212 is not connected to any conductive pad 300 disposed at the second metal level.

In some embodiments, the plurality of connection structures 200 may include connection structures 210_1, 210_2, and 211_1 having a first height as measured from the upper surface 100us of the first restive line 100 to an upper surface of the connection structures 210_1, 210_2, and 211_1, and a connection structure 212 may have a second height as measured from the upper surface 100us of the first resistive line to an upper surface of the connection structure 212, and the second height may be smaller than or less than the first height.

Each conductive pad 300 may be connected to a respective one connection structure 200, but the number of the plurality of connection structures 200 is larger than the number of the plurality of conductive pads 300. Also, the upper contact may not be formed on some of the plurality of conductive insertion pads 230_1, 230_2, and 231_1. As such the number of the upper contacts disposed in the third insulating film 80 may be different from the number of the lower contacts disposed in the second insulating film 70.

In FIG. 6, the second conductive node pad 301_2 connected to the second node connection structure 210_2 is illustrated as overlapping the third dummy node connection structure 212 in a third direction perpendicular to the upper surface 100us of the first resistive line 100, but the inventive concepts provided herein are not limited thereto. That is, in some embodiments the second conductive node pad 301_2 may not overlap the third dummy node connection structure 212 in the third direction.

In some embodiments, rather than the configuration illustrated in FIG. 6, the conductive dummy pad 302 on the first dummy node connection structure 212 adjacent to the third dummy node connection structure 212 may overlap the third dummy node connection structure 212 in a direction perpendicular to the upper surface 100us of the first resistive line 100.

Referring to FIG. 7, in a semiconductor device according to some embodiments, the first conductive node pad 301_1 may be connected to a plurality of first node connection structures 210_1, and the second conductive node pad 301_2 may be connected to a plurality of second node connection structures 210_2.

In some embodiments, one of the first conductive node pad 301_1 and the second conductive node pad 301_2 may be connected to a plurality of node connection structures, and the other thereof may be connected to one connection structure.

Since one conductive pad 300 may be connected to a plurality of connection structures 200, the number of the plurality of connection structures 200 may be larger than the number of the plurality of conductive pads 300.

Referring to FIG. 8, in a semiconductor device according to some embodiments, the plurality of conductive pads 300 may include at least one first conductive node pad 301_1, at least one second conductive node pad 301_2, at least one conductive dummy pad 302, and at least one conductive connection pad 303. The conductive connection pad 303 may be connected to a plurality of first dummy node connection structures 211_1.

A current path between the first conductive node pad 301_1 and the second conductive node pad 301_2 may be the first node connection structure 210_1, the first resistive line 100, the first dummy node connection structure 211_1 connected to the conductive connection pad 303, the first resistive line 100, and the second node connection structure 210_2.

Since one conductive pad 300 may be connected to a plurality of connection structures 200, the number of the plurality of connection structures 200 may be larger than the number of the plurality of conductive pads 300.

In FIGS. 2 through 8, the resistance corresponding to one resistive region 100_1 of the first resistive line 100 is assumed as Rₐ, and the resistances of each of the node connection structures 210_1 and 210_2 are assumed as R_{b}.

In FIGS. 3, 5 and 6, the number of resistive regions 100_1 located between the first node connection structure 210_1 and the second node connection structure 210_2 is five. At this time, it is possible to expect that the resistance value Rₖ₊₂ between the first conductive node pad 301_1 and the second conductive node pad 301_2 roughly has a value of 2R_{b}+5Rₐ.

In FIG. 7, the number of resistive regions 100_1 located between the first node connection structure 210_1 and the second node connection structure 210_2 is three. At this time, it is possible to expect that the resistance value Rₖ₊₂ between the first conductive node pad 301_1 and the second conductive node pad 301_2 roughly has a value of 2R_{b}+3Rₐ.

In FIG. 8, the number of resistive regions 100_1 located between the first node connection structure 210_1 and the second node connection structure 210_2 is four. At this time, it is possible to expect that the resistance value Rₖ₊₂ between the first conductive node pad 301_1 and the second conductive node pad 301_2 roughly has a value of 2R_{b}+4Rₐ.

The resistance value Rₖ₊₂ between the first conductive node pad 301_1 and the second conductive node pad 301_2 may variously change, depending on how to form the plurality of conductive pads 300.

When the resistance value of one resistive region 100_1 and the resistance value of one of the node connection structures 210_1 and 210_2 are known in advance, the resistance value between the adjacent voltage nodes may be adjusted by adjusting only the arrangement of the conductive pad 300. Through adjustment of the resistance value between the adjacent voltage nodes, the distributed voltage extracted from the voltage nodes may also be adjusted.

For example, a pre substrate formed up to the conductive insertion pads 230_1, 230_2 and 231_1 or a pre substrate formed up to the upper contacts 240_1, 240_2 and 241_1 may be manufactured in advance. Prior to completion of manufacturing of the semiconductor device, a user who uses the semiconductor device may order the semiconductor device and specify details regarding one or more needed distributed voltages. In such a case, the manufacturer of the semiconductor device may quickly secure the placement of the conductive pad 300 through the combination of the resistance values known in advance. In addition, the semiconductor device may be rapidly manufactured, using the pre substrate on which at least a part of the connection structure connected to the resistive line is formed.

In addition, since a plurality of voltage nodes is formed on one resistive line, the area occupied by the resistance structure in the semiconductor device may be reduced.

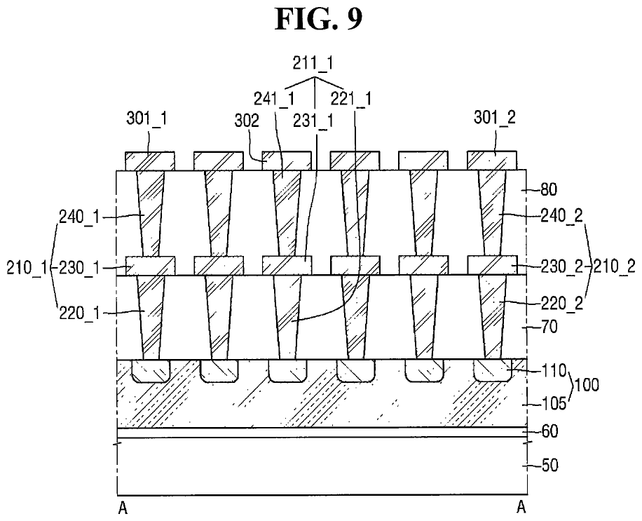

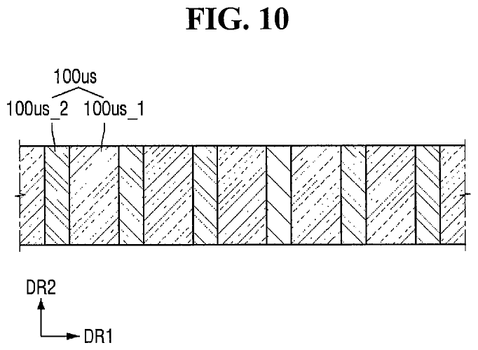

FIGS. 9 and 10 are diagrams illustrating a semiconductor device according to some embodiments. For convenience of explanation, aspects presented within FIGS. 9 and 10 differing from those described using FIGS. 2 to 4 will be mainly described. For reference, FIG. 9 is a view taken along the line A-A of FIG. 2, and FIG. 10 is an exemplary top view of the first resistive line 100 in a portion corresponding to the line A-A of FIG. 2.

Referring to FIGS. 9 and 10, in a semiconductor device according to some embodiments, the upper surface 100us of the first resistive line may include one or more first regions 100us_1 and one or more second regions 100us_2.

Each first region 100us_1 of the upper surface 100us of the first resistive line 100 is a region formed by the semiconductor material of the semiconductor pattern 105, and each second region 100us_2 of the upper surface 100us of the first resistive line 100 is a region formed by silicide of the film 110.

The first node connection structure 210_1, the second node connection structure 210_2, and the first dummy node connection structure 211_1 may be connected to one or more second regions 100us_2 of the upper surface 100us of the first resistive line 100.

In some embodiments, in the upper surface 100us of the first resistive line, the one or more first regions 100us_1 of the upper surface 100us of the first resistive line 100 and the one or more second regions 100us_2 of the upper surface 100us of the first resistive line 100 may be alternately arranged in the first direction DR1.

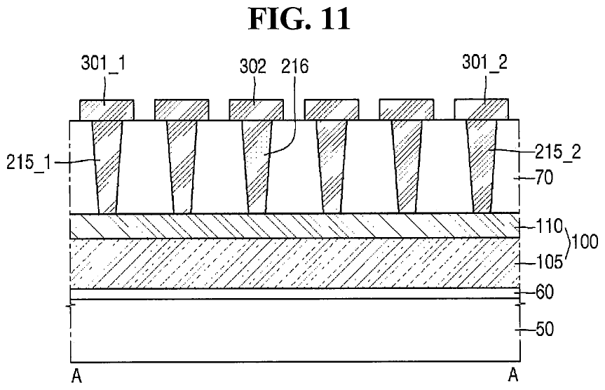

FIG. 11 is a diagram illustrating a semiconductor device according to some embodiments. For convenience of explanation, aspects presented within FIG. 11 differing from those described using FIGS. 2 to 4 will be mainly described.

Referring to FIGS. 2 and 11, in a semiconductor device according to some embodiments, the plurality of connection structures 200 may include at least one third node connection structure 215_1, at least one fourth node connection structure 215_2 and at least one fourth dummy connection structure 216.

The third node connection structure 215_1, the fourth node connection structure 215_2, and the fourth dummy connection structure 216 may correspond respectively to the lower contacts (220_1, 220_2 and 221_1 of FIG. 3) of the first node connection structures (210_1 of FIG. 3), the second node connection structure (210_2 of FIG. 3) and the first dummy node connection structure (211_1 of FIG. 3).

The third node connection structure 215_1 may extend from the first resistive line 100 to a first conductive node pad 301_1, and the fourth node connection structure 215_2 may extend from the first resistive line 100 to a second conductive node pad 301_2. The fourth dummy connection structure 216 may extend from the first resistive line 100 to a conductive dummy pad 302.

The third node connection structure 215_1, the fourth node connection structure 215_2, and the fourth dummy connection structure 216 may lack the conductive insertion pads 230_1, 230_2 and 231_1 of FIG. 3 and the upper contacts 240_1, 240_2 and 241_1. Also absent from the semiconductor device according to some embodiments may be the third insulating film 80.

The third node connection structure 215_1 may be connected to the first conductive node pad 301_1, and the fourth node connection structure 215_2 may be connected to the second conductive node pad 301_2. The fourth dummy connection structure 216 may be connected to the conductive dummy pad 302.

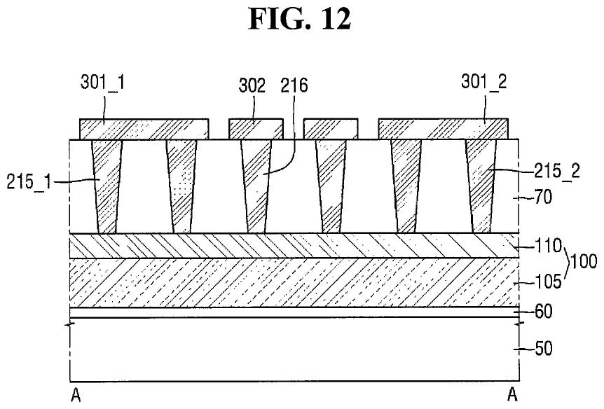

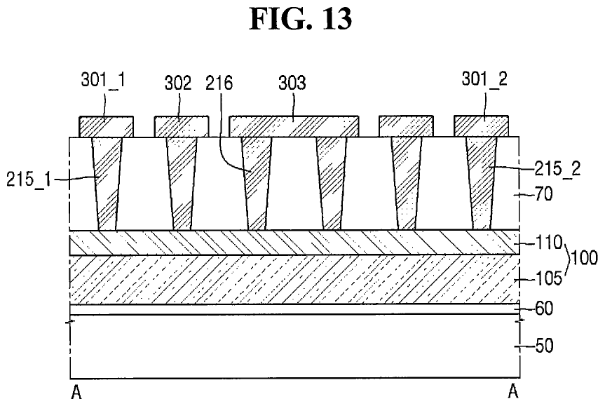

FIG. 12 is a diagram illustrating a semiconductor device according to some embodiments. FIG. 13 is a diagram illustrating a semiconductor device according to some embodiments. For convenience of description, aspects presented within FIGS. 12 and 13 differing from those described using FIG. 11 will be mainly described.

Referring to FIG. 12, a first conductive node pad 301_1 may be connected to a plurality of third node connection structures 215_1, and a second conductive node pad 301_2 may be connected to a plurality of fourth node connection structures 215_2.

In some embodiments, one of the first conductive node pad 301_1 and the second conductive node pad 301_2 may be connected to the plurality of node connection structures, and the other thereof may be connected to one node connection structure.

Referring to FIG. 13, the plurality of conductive pads (300 of FIG. 2) may include at least one first conductive node pad 301_1, at least one second conductive node pad 301_2, at least one conductive dummy pad 302, and at least one conductive connection pad 303. The conductive connection pad 303 may be connected to the plurality of fourth dummy node connection structures 216.

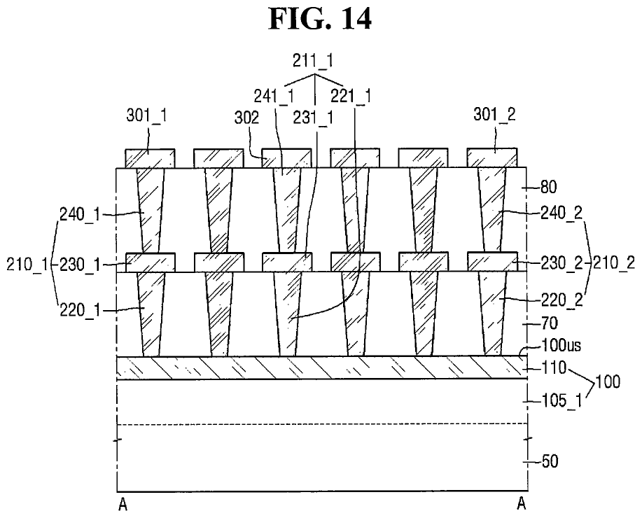

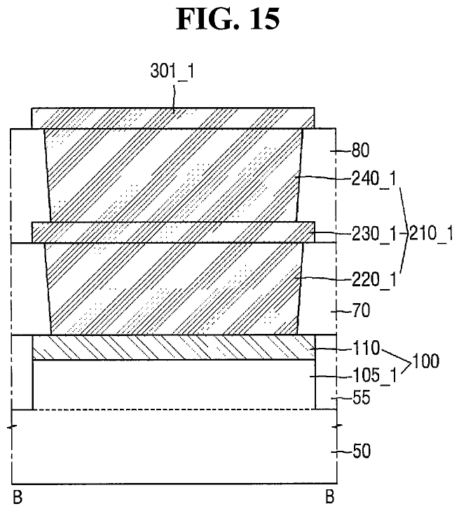

FIGS. 14 and 15 are diagrams illustrating a semiconductor device according to some embodiments. For convenience of explanation, aspects presented within FIGS. 14 and 15 differing from those described using FIGS. 2 to 4 will be mainly described. For reference, FIG. 14 is a diagram taken along the line A-A of FIG. 2, and FIG. 15 is a diagram taken along the line B-B of FIG. 2.

Referring to FIGS. 14 and 15, in a semiconductor device according to some embodiments, the first resistive line 100 is defined by an element isolation film 55 formed in the substrate 50.

The first resistive line 100 may include a semiconductor region 105_1 which is a part of the substrate 50, and a silicide film 110 on the semiconductor region 105_1.

The semiconductor region 105_1 and the silicide film 110 may be surrounded by the element isolation film 55. The first insulating film 60 may be absent from the semiconductor device according to some embodiments, and substantially vertical surfaces of the long sidewalls 100a and short sidewalls 100b of the first resistive line 100 may be free from contact with the second insulating film 70, and may instead contact the element isolation film 55.

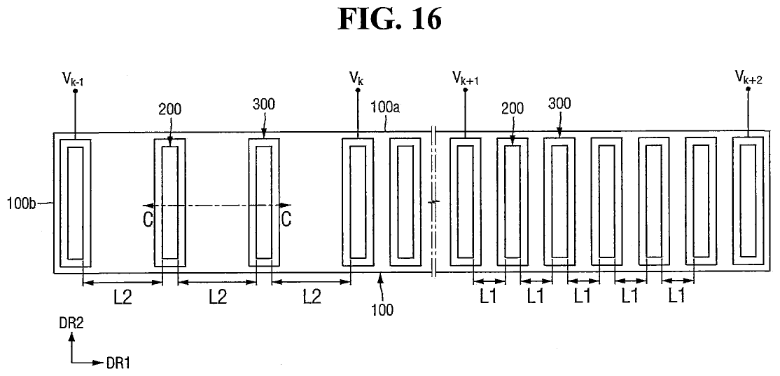

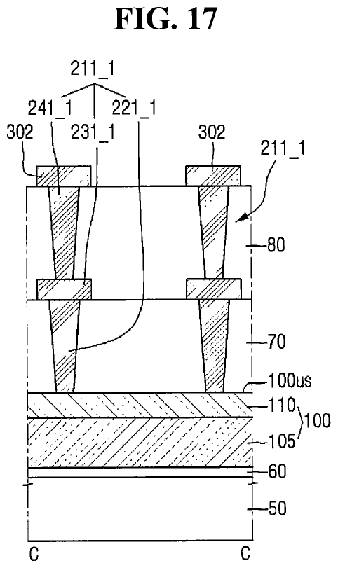

FIG. 16 is a layout diagram illustrating a semiconductor device according to some embodiments. FIG. 17 is a cross-sectional view taken along line C-C of FIG. 16. For convenience of explanation, aspects presented within FIGS. 16 and 17 differing from those described using FIGS. 2 to 4 will be mainly described.

Referring to FIGS. 16 and 17, in a semiconductor device according to some embodiments, some of the plurality of connection structures 200 may be separated from each other in the first direction DR1 by a first distance L1. In addition, some of the connection structures 200 may be separated from each other in the first direction DR1 by a second distance L2 that is larger than the first distance L1.

Stated differently, the plurality of connection structures 200 may include connection structures 200 spaced apart by the first distance L1 and adjacent to each other, and connection structures 200 spaced part by the second distance L2 and adjacent to each other.

The resistance value of the resistive region defined between adjacent connection structures 200 spaced apart by the first distance L1 differs from the resistance value of the resistive region defined between the adjacent connection structures 200 spaced apart by the second distance L2. Thus, a distributed voltage extracted from the voltage nodes may be variously adjusted by variously adjusting the resistance value between the adjacent voltage nodes.

The adjacent connection structures 200 spaced apart by the first distance L1 and the adjacent connection structures 200 spaced apart by the second distance L2 may be connected to the first resistance line 100 and may have similar structures, such as the various connection structures described elsewhere herein.

In FIG. 17, illustration of the conductive dummy pad 302 and the first dummy node connection structure 211_1 are provided merely as an example, and the inventive concepts provided herein are not limited thereto. As illustrated in FIGS. 5 through 8, the structure and placement of the connection structure 200 and the placement of the conductive pad 300 may be various.

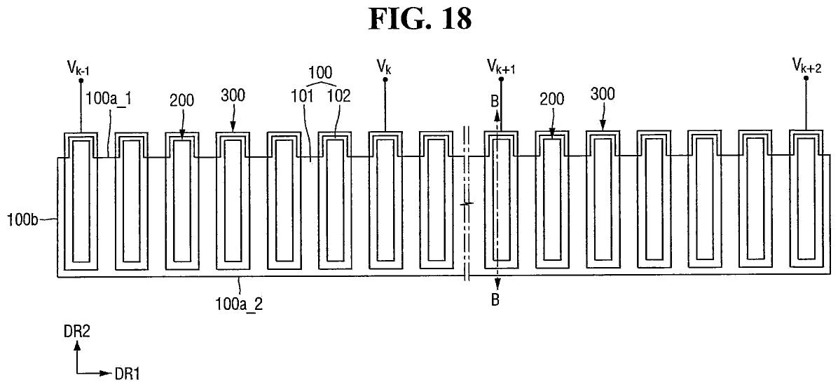

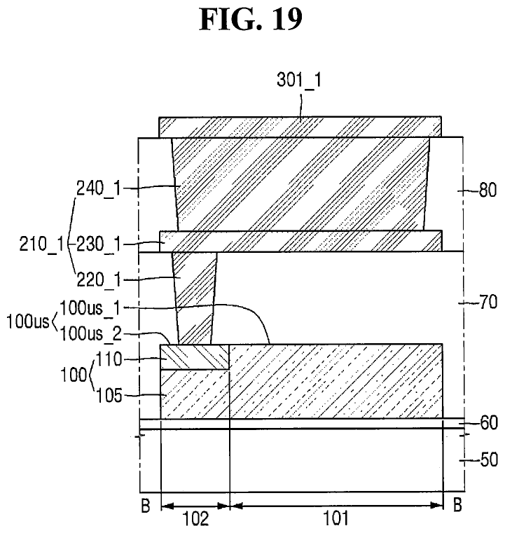

FIG. 18 is a layout diagram illustrating a semiconductor device according to some embodiments. FIG. 19 is a cross-sectional view taken along line B-B of FIG. 18. For convenience of explanation, aspects presented within FIGS. 18 and 19 differing from those described using FIGS. 2 to 4 will be mainly described.

Referring to FIGS. 18 and 19, in a semiconductor device according to some embodiments, the first resistive line 100 may include a line pattern 101 and a first protrusion pattern 102.

The first resistive line 100 may include a first long sidewall 100a_1 and a second long sidewall 100a_2 extending in the first direction DR1. A short sidewall 100b of the first resistive line 100 connects the first long sidewall 100a_1 of the first resistive line and the second long sidewall 100a_2 of the first resistive line 100 facing each other.

The line pattern 101 of the first resistive line 100 may have a line shape extending in the first direction DR1. The first protrusion pattern 102 of the first resistive line 100 may protrude from the first long sidewall 100a_1 of the first resistive line 100 in the second direction DR2.

The silicide film 110 may be included in the first protrusion pattern 102 of the first resistive line 100. An upper portion of the first protrusion pattern 102 of the first resistive line 100 may include a region formed of silicide of the silicide film 110.

The first region 100us_1 of the upper surface 100us of the first resistive line 100 is a region formed by the semiconductor material of the semiconductor pattern 105, and the second region 100us_2 of the upper surface 100us of the first resistive line 100 is a region formed by silicide of the silicide film 110. The upper surface of the first protrusion pattern 102 of the first resistive line 100 includes a second region 100us_2 of the upper surface 100us of the first resistive line 100.

The first node connection structure 210_1 may be connected to the upper surface of the first protrusion pattern 102 of the first resistive line formed of silicide.

The lower contact 220_1 of the first node connection structure 210_1 may be connected to the upper surface of the first protrusion pattern 102 of the first resistive line.

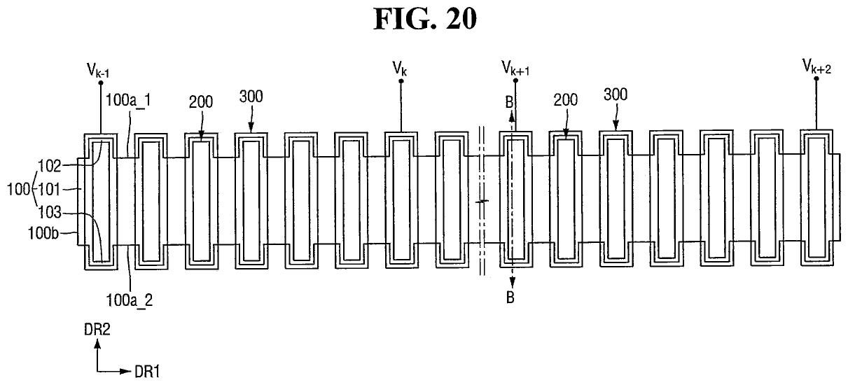

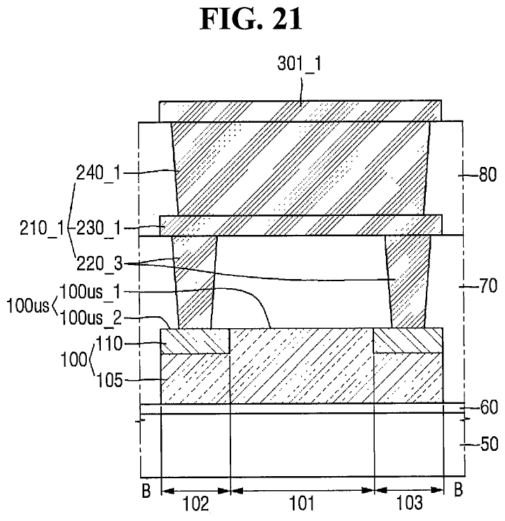

FIG. 20 is a layout diagram illustrating a semiconductor device according to some embodiments. FIG. 21 is a cross-sectional view taken along line B-B of FIG. 20. For convenience of explanation, aspects presented within FIGS. 20 and 21 differing from those described using FIGS. 18 and 19 will be mainly described.

Referring to FIGS. 20 and 21, in the semiconductor device according to some embodiments, the first resistive line 100 may further include a second protrusion pattern 103.

The second protrusion pattern 103 of the first resistive line 100 may protrude from the second long sidewall 100a_2 of the first resistive line 100 in the second direction DR2. The second protrusion pattern 103 of the first resistive line 100 may be disposed at a position corresponding to the first protrusion pattern 102 of the first resistive line 100.

The silicide film 110 may be included in the first protrusion pattern 102 of the first resistive line and the second protrusion pattern 103 of the first resistive line 100. An upper portion of the first protrusion pattern 102 of the first resistive line 100 and an upper portion of the second protrusion pattern 103 of the first resistive line 100 may include a region formed of silicide of the silicide film 110.

The upper surface of the first protrusion pattern 102 of the first resistive line 100 and the upper surface of the second protrusion pattern 103 of the first resistive line 100 may include a second region 100us_2 of the upper surface 100us of the first resistive line 100.

The first node connection structure 210_1 may include lower contacts 220_3 spaced apart in the second direction DR2. The lower contacts 220_3 spaced apart in the second direction DR2 may be connected through the conductive insertion pads 230_1. The lower contacts 220_3 spaced apart in the second direction DR2 may be connected to the upper surface of the first protrusion pattern 102 of the first resistive line and the upper surface of the second protrusion pattern 103 of the first resistive line, respectively.

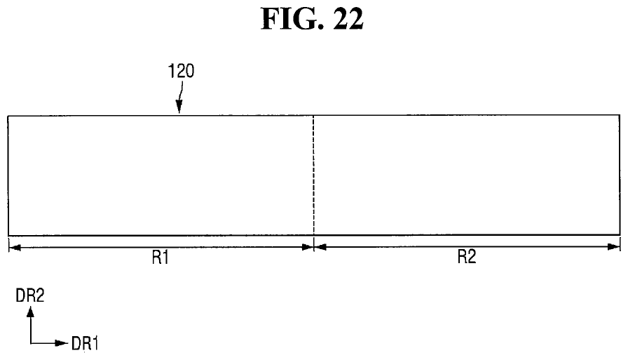

FIG. 22 is a diagram illustrating resistive lines included in a semiconductor device according to some embodiments.

Referring to FIG. 22, in a semiconductor device according to some embodiments, a second resistive line 120 extending in the first direction may include a first region R1 and a second region R2.

The first region R1 of the second resistive line 120 may have a structure different from the second region R2 of the second resistive line 120. Here, the term “different structure” may mean that the position at which the silicide is formed differs, and may mean that the presence or absence of the protrusion pattern differs. Alternatively, the term “different structure” may mean that the formed position of the protrusion pattern differs.

As an example, the first region R1 of the second resistive line 120 may have the structure of the first resistive line 100 described using FIGS. 3 to 8, and the second region R2 of the second resistive line 120 may have the structure of the first resistive line 100 described using FIGS. 9 and 10.

As another example, the first region R1 of the second resistive line 120 may have the structure of the first resistive line 100 described using FIGS. 3 to 8, and the second region R2 of the second resistive line 120 may have the structure of the first resistive line 100 described using FIGS. 18 and 19.

As still another example, the first region R1 of the second resistive line 120 may have the structure of the first resistive line 100 described using FIGS. 3 to 8, and the second region R2 of the second resistive line 120 may have the structure of the first resistive line 100 described using FIGS. 20 and 21.

As still another example, the first region R1 of the second resistive line 120 may have the structure of the first resistive line 100 described using FIGS. 9 and 10, and the second region R2 of the second resistive line 120 may have the structure of the first resistive line 100 described using FIGS. 18 and 19 or the structure of the first resistive line 100 described using FIGS. 20 and 21.

As still another example, the first region R1 of the second resistive line 120 may have the structure of the first resistive line 100 described using FIGS. 18 and 19, and the second region R2 of the second resistive line 120 may have the structure of the first resistive line 100 described using FIGS. 20 and 21.

Since the structures of the second resistive line 120 described above are only some examples that the second resistive line 120 may have, the structures are not limited thereto.

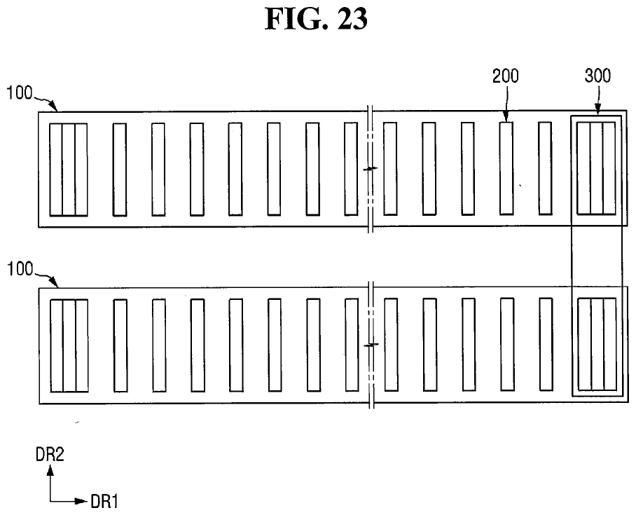

FIG. 23 is a diagram illustrating a plurality of resistive lines included in a semiconductor device according to some embodiments. For reference, the conductive pad 300 is illustrated only in the portion connecting the adjacent resistive lines.

Further, since the description of the first resistive line 100 and the plurality of connection structures 200 may overlap with the contents described above, the description thereof may not be omitted in the interest of brevity.

Referring to FIG. 23, in the semiconductor device according to some embodiments, a plurality of first resistive lines 100 may be sequentially arranged in the second direction DR2.

The first resistive lines 100 may be connected using the conductive pad 300. The conductive pads 300 may be connected to one or more connection structures 200 that are connected to the respective first resistive lines 100.

In some embodiments, in order to minimize an increase in resistance value caused by the connection of the first resistive lines 100, a plurality of connection structures 200 of each first resistive line 100 may be bound together and connected to the conductive pad 300.

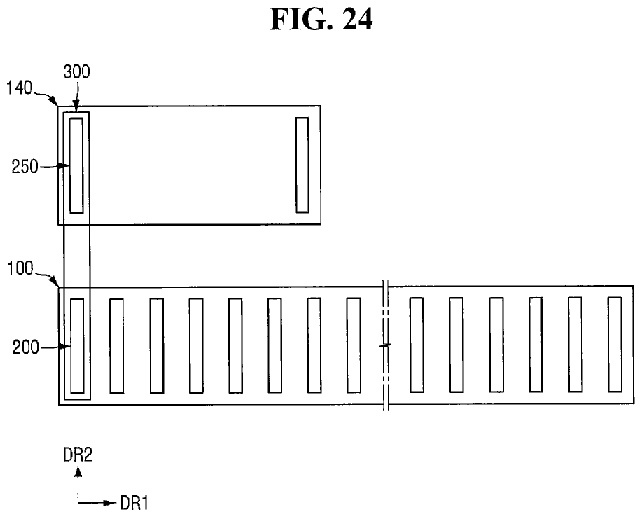

FIG. 24 is a diagram illustrating a plurality of resistive lines included in a semiconductor device according to some embodiments. For reference, the conductive pad 300 is only illustrated in the portion connecting the adjacent resistive lines.

Further, since the description of the first resistive line 100 and the plurality of connection structures 200 may overlap with the contents described above, the description thereof may not be omitted herein in the interest of brevity.

Referring to FIG. 24, in a semiconductor device according to some embodiments, a first resistive line 100 may be connected to a third resistive line 140 by the conductive pad 300.

Only the two unit connection structures 250 may be formed on the third resistive line 140. The unit connection structures 250 may be connected to the third resistive line 140. Since the unit connection structures 250 connected to the third resistive line 140 are two, the third resistive line 140 is connected to the two voltage nodes.

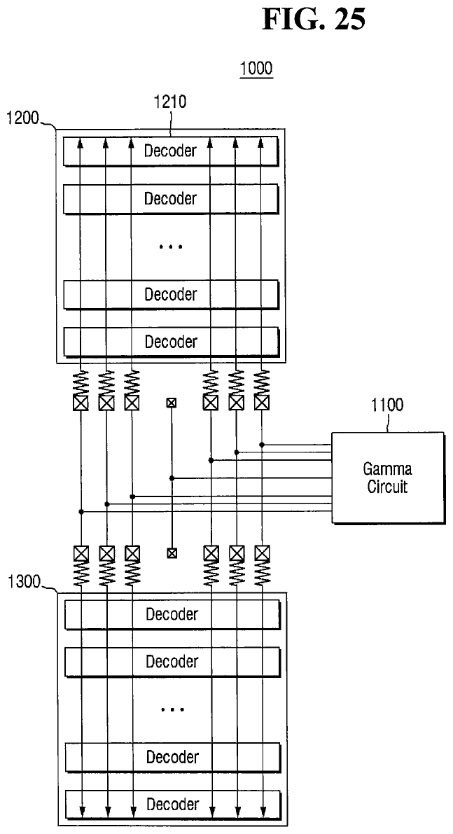

FIG. 25 is a diagram schematically illustrating a display driver integrated circuit including a semiconductor device according to some embodiments.

Referring to FIG. 25, a display driver integrated circuit 1000 may include a gamma circuit 1100 formed on the substrate 50 of FIG. 3 and source drivers 1200 and 1300.

The gamma circuit 1100 may include any of the semiconductor devices described using FIGS. 2 through 24.

The source drivers 1200 and 1300 may include a plurality of decoders 1210 that are formed on the substrate 50 to decode data signals transmitted from the gamma circuit 1100.

The plurality of decoders 1210 may select and output one of the plurality of gamma voltages provided from the gamma circuit 1100.

Those skilled in the art will appreciate that many variations and modifications may be made to the preferred embodiments without substantially departing from the principles of the present inventive concepts. Therefore, the disclosed embodiments of the inventive concepts are used in a generic and descriptive sense only and not for purposes of limitation.

1. A semiconductor device comprising:
a plurality of connection structures arranged in a first direction;
a resistive line connected to the plurality of connection structures and including a plurality of resistive regions arranged in the first direction, each of the resistive regions being defined between a respective pair of adjacent connection structures of the plurality of connection structures; and
a plurality of conductive pads on the plurality of connection structures and connected to the resistive line,
wherein some of the plurality of conductive pads are configured for use as voltage nodes.

2. The semiconductor device of claim 1, wherein the plurality of connection structures includes a first node connection structure and a second node connection structure, and wherein each of the first and second node connection structures includes a lower contact on the resistive line, a conductive insertion pad on the lower contact, and an upper contact on the conductive insertion pad.

3. The semiconductor device of claim 2, wherein the first node connection structure and the second node connection structure are adjacent to each other, and wherein a first of the some conductive pads configured for use as voltage nodes is connected to the first node connection structure, and a second of the some conductive pads configured for use as voltage nodes is connected to the second node connection structure.

4. The semiconductor device of claim 2, wherein the first node connection structure and the second node connection structure are adjacent to each other, wherein the plurality of conductive pads includes a first conductive pad, and wherein the first conductive pad is connected to the first node connection structure and not connected to the second node connection structure.

5. The semiconductor device of claim 1, wherein the plurality of connection structures further includes at least one or more dummy connection structures, wherein the dummy connection structure includes a contact on the resistive line, and a conductive insertion pad on the contact, and wherein the dummy connection structure is not connected to the plurality of conductive pads.

6. The semiconductor device of claim 1, wherein the connection structure includes a plurality of contacts arranged in the first direction, and wherein each of the plurality of contacts extends from the resistive line to the conductive pad.

7. The semiconductor device of claim 6, wherein the plurality of contacts includes a first contact and a second contact adjacent to each other in the first direction, and wherein one of the plurality of conductive pads is connected to the first contact and to the second contact.

8. The semiconductor device of claim 1, wherein the resistive line includes a semiconductor pattern and a silicide film on an upper surface of the semiconductor pattern.

9. The semiconductor device of claim 1, wherein an upper surface of the resistive line includes a first region comprising a semiconductor material and a second region comprising a silicide, and wherein the plurality of connection structures is connected to the second region of the upper surface of the resistive line.

10-12. (canceled)

13. The semiconductor device of claim 1, wherein a first end of the resistive line is connected to a first voltage, and a second end of the resistive line opposite from the first end is connected to a second voltage different from the first voltage, and wherein each conducive pad is configured to provide a distributed voltage between the first voltage and the second voltage.

14-15. (canceled)

16. A semiconductor device comprising:
a resistive line extending in one direction;
a plurality of connection structures connected to the resistive line and spaced at equal intervals in the one direction; and
a plurality of conductive pads on a first metal level and connected to at least some of the plurality of connection structures,
wherein the plurality of connection structures includes:
a plurality of lower contacts spaced on the resistive line in the one direction, and
a plurality of conductive insertion pads, each conductive insertion pad corresponding to a respective one of the plurality of lower contacts and connected thereto, and each conductive insertion pad at a second metal level lower than the first metal level.

17. The semiconductor device of claim 16, wherein the plurality of connection structures includes a plurality of upper contacts, each upper contact corresponding to a respective one of the plurality of conductive insertion pads and between the respective conductive insertion pad and the plurality of conductive pads.

18. The semiconductor device of claim 17, wherein each of the plurality of upper contacts connects of the respective one of the plurality of conductive insertion pads to one of the plurality of conductive pads.

19. The semiconductor device of claim 16, wherein the plurality of connection structures includes a node connection structure connected to the conductive pad, and a dummy connection structure not connected to the conductive pad, wherein the node connection structure includes an upper contact connecting one of the plurality of conductive insertion pads with one of the plurality of conductive pads, and wherein the dummy connection structure lacks a connection between the first metal level and the second metal level.

20. The semiconductor device of claim 16, wherein the plurality of conductive pads includes a first conductive pad configured to extract a first distributed voltage, and a second conductive pad configured to extract a second distributed voltage different from the first distributed voltage,
the plurality of connection structures includes a first connection structure connected to the first conductive pad, and a second connection structure connected to the second conductive pad, and
the plurality of connection structures includes at least one or more third connection structures between the first connection structure and the second connection structure and connected to the resistive line but not connected to a conductive pad.

21. The semiconductor device of claim 20, wherein the plurality of conductive pads includes a third conductive pad disposed between the first conductive pad and the second conductive pad and connected to a first of the third connection structures.

22-34. (canceled)

35. A semiconductor device comprising:
first and second resistive lines;
a plurality of first voltage node structures connected to the first resistive line, each first voltage node structure including a first connection structure and a first conductive pad on the first connection structure;
a plurality of second voltage node structures connected to the second resistive line, each second voltage node structure including a second connection structure and a second conductive pad on the second connection structure; and
a connection conductive pad connecting the first resistive line with the second resistive line,
wherein each first voltage node structure configured to extract a different voltage, and
wherein each second voltage node structure is configured to extract a different voltage.

36. The semiconductor device of claim 35, further comprising:
at least one or more dummy voltage node structures connected to at least one of the first resistive line and the second resistive line,
wherein the dummy voltage node structures are not configured to extract voltages.

37. The semiconductor device of claim 35, wherein the connection conductive pad is at the same metal level as the first and second conductive pads.

38. The semiconductor device of claim 35, wherein each of the first and second voltage node structures includes a lower contact, an upper contact, and a conductive insertion pad connecting the lower contact and the upper contact.
